(19) United States
(12) Patent Application Publication
(10) Pub. No.: US 2010/0226178 A1
(43) Pub. Date: Sep. 9, 2010

(54) APPARATUS AND METHODS FOR CORRECTING OVER-ERASED FLASH MEMORY CELLS

(75) Inventors: Thomas Nirschl, Munich (DE); Jan Otterstedt, Unterhaching (DE)

Correspondence Address: Viering, Jentschura & Partner, 3770 Highland Ave., Suite 203, Manhattan Beach, CA, 90266, US

(73) Assignee: INFINEON TECHNOLOGIES AG, Neubiberg (DE)

(21) Appl. No.: 12/398,258

(22) Filed: Mar. 5, 2009

(51) Int. Cl. G11C 16/04; G11C 16/06

(52) U.S. Cl. 365/185.09; 365/185.3; 365/185.19

(57) ABSTRACT

A method and flash memory device that correct over-erased memory cells are described. The device includes flash memory cells, erase circuitry, measuring circuitry, and a pulse generator. The method includes performing an erase operation on a first plurality of memory cells, measuring at least one memory cell of a second plurality of memory cells, and if an over-erased memory cell is detected in measuring the second plurality of cells, applying one or more programming pulses to the one or more over-erased cells, the one or more programming pulses cumulatively sufficient to correct a cell in a maximum over-erased state. Also described is a method that registers over-erased cells for programming and applies one or more programming pulses to the registered over-erased cells, the one or more programming pulses cumulatively sufficient to correct a cell in a maximum over-erased state.

### BACKGROUND OF THE INVENTION

Flash memory continues to be scaled to smaller and smaller dimensions. Although scaling down enables placing larger amounts of memory in a same sized footprint, problems may arise when memory cells are scaled down. For example, at a sufficiently small scale, memory cells exhibit non-uniform behavior.

Non-uniform behavior is especially problematic when a flash memory device performs a block erase. In a block erase, a large number of cells are exposed to an electrical charge in order to erase a “block” of memory by attempting to place the cells within a threshold voltage distribution (i.e., the erase distribution). Typically, the threshold voltage of a cell is altered, thereby erasing the cell, by changing the magnitude of the floating gate charge within the cell. Some cells within a block are slower to erase than others partly due to different floating gate charges on the cells before the block erase as well as intrinsic qualities of flash memory cells. When a block erase occurs, then, a distribution curve of threshold voltages will result, with some of the fastest erasing cells lying outside the intended erase distribution. Because the threshold voltage of the fast-erasing cells are below the lower limit of the erase distribution, these cells are in an over-erased state.

Over-erased cells are undesirable because they cause false data reads for electrically-coupled cells. For example, cells that share a bitline with an over-erased cell and are programmed to a logical 1, may now be read as a logical 0. This is because over-erased cells constantly draw current even while not being selected themselves and thus virtually lower the threshold voltage of the other cells. In severe cases, a single over-erased cell may disable an entire bitline. In another case, many cells may be slightly over-erased, resulting in a cumulative bitline leakage current.

### SUMMARY OF THE INVENTION

Embodiments of the invention provide methods and flash memory devices that correct over-erased memory cells. The flash memory devices include flash memory cells, erase circuitry, measuring circuitry, and a pulse generator. The methods include performing an erase operation on a first plurality of memory cells, measuring at least one memory cell of a second plurality of memory cells, and if one or more over-erased cells are detected in measuring the second plurality of cells, applying one or more programming pulses to the one or more over-erased cells, the one or more programming pulses cumulatively sufficient to correct a cell in a maximum over-erased state.

Embodiments further provide a method that corrects a series of errors in a flash memory. The method includes detecting an over-erased cell, wherein the over-erased cell prevents at least one other cell from being properly read, and applying one or more programming pulses to the over-erased cell, the one or more programming pulses cumulatively sufficient to correct a cell in a maximum over-erased state.

Embodiments further provide a method correcting over-erased memory cells. The method includes performing an erase operation on a first plurality of cells, measuring at least one cell of a second plurality of cells, if one or more over-erased cells are detected in measuring the second plurality of cells, registering the one or more over-erased cells for programming, and applying one or more programming pulses to the registered over-erased cells, the one or more programming pulses cumulatively sufficient to correct a cell in a maximum over-erased state.

These and other features of the invention will be better understood when taken in view of the following drawings and a detailed description.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a graphical representation of threshold voltage distributions of memory cells.

FIG. 2A is a flowchart of a process for correcting over-erased memory cells, in accordance with an embodiment of the invention;

FIG. 2B is a flowchart of a process for reading memory cells, in accordance with an embodiment of the invention;

FIG. 3 shows a simplified diagram of a typical flash memory array, in accordance with an embodiment of the invention;

FIG. 4 is a flowchart of a process for correcting over-erased memory cells, in accordance with an embodiment of the invention;

FIG. 5 is a flowchart of a process for correcting over-erased memory cells, in accordance with an embodiment of the invention;

FIGS. 6A and 6B are flowcharts of processes for correcting over-erased memory cells, in accordance with an embodiment of the invention; and

FIG. 7 shows a block diagram of one embodiment of an electronic system, in accordance with an embodiment of the invention.

### DETAILED DESCRIPTION OF ILLUSTRATIVE EMBODIMENTS

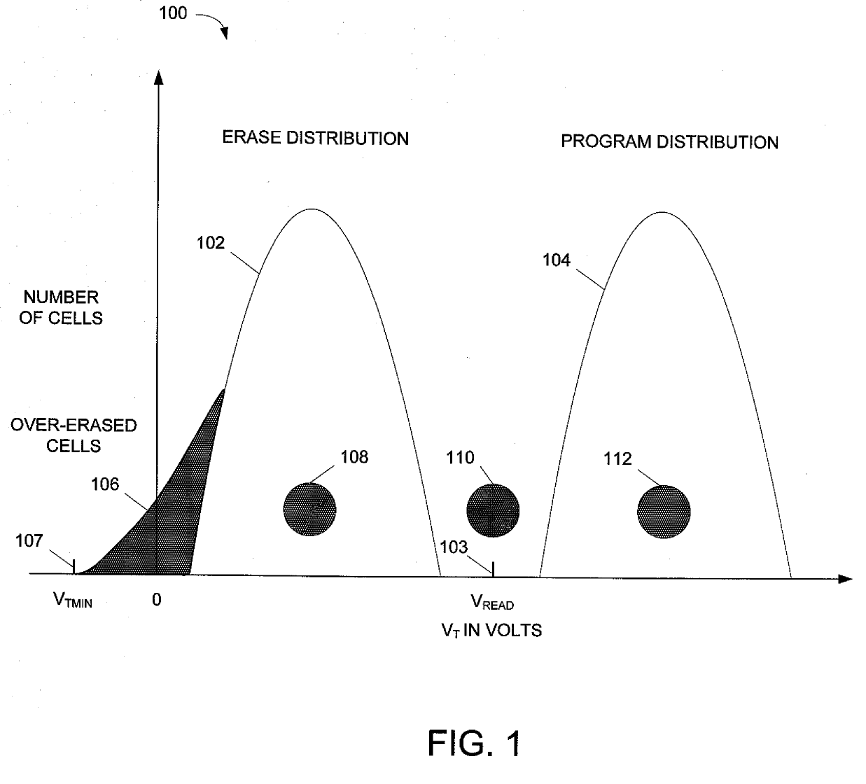

As described above, flash memory cells (also referred to as “memory cells” or “cells”) behave in a non-uniform manner during a block erase. This is shown by the graph of FIG. 1. When a block erase occurs, threshold voltages of flash memory cells are placed within erase distribution 102. When read voltage V_{READ} 103 is placed on the cell, current is conducted, signifying a logic bit 1 or 0. Ideally, all erased cells would fall within erase distribution 102; however, some cells may be over-erased, as in the case of over-erase distribution 106.

One conventional technique to decrease the amount of over-erased cells from a block erase is to pre-program cells prior to an erase operation so that all of the cells that are to be erased have the same threshold voltage. This technique, however, limits but does not prevent over-erased cells. Soft programming is another conventional technique which re-shapes over-erased distribution 106 by sending programming pulses to an over-erased cell until a measured threshold voltage of the cell is within erase distribution 102. This technique greatly increases block erase time of a flash memory device because cells are corrected and checked in a step-wise manner. Another conventional technique applies a negative voltage to cells not being read to prevent currents from over-erased cells affecting cells that are being read. This technique requires additional power and circuitry. Another conventional technique organizes cells into sector selects, with each sector being electronically isolated from another. This technique requires additional area to implement and isolates rather than corrects over-erased cells.

Error correction codes are another conventional technique which may be used in tandem with the above described techniques. Error correction codes (also referred to as “ECC”) are limited in the number of errant bits they can correct. If an over-erased cell is causing false reads for electrically-coupled cells, the error rate will go up significantly and perhaps past the capability of an ECC due to a single erroneous over-erased bit.

According to various embodiments of the invention, it is possible to avoid size penalties but have a short erase time and low-power consumption when correcting over-erased cells. It is also possible to avoid an increase error rate due to an over-erased cell, where, in some embodiments, an ECC may correct for fewer errant bits. As detailed below, embodiments of the invention provide a method of erasing flash memory that applies one or more programming pulses, the one or more programming pulses cumulatively sufficient to correct a cell in a maximum over-erased state.

An example of a maximum over-erased state is shown in FIG. 1. Minimal threshold voltage 107 marks the maximum over-erased state a cell may reach. The more a cell is over-erased, the lower its threshold voltage becomes. A maximum over-erased state may be determined by many variables, which include physical size of a cell, duration and amplitude of erase signal, and the history of the cell (e.g., the number cycles the cell has gone through or the threshold voltage of the cell before an erase operation). Through empirical testing or modeling a maximum over-erased state may be determined for a flash memory and/or block erase operation. In some embodiments, the maximum over-erased state is determined by the flash device itself, wherein the flash device may update its definition of the maximum over-erased state to accommodate, for example, changing memory cell characteristics or erase operations.

An over-erased cell may have a voltage threshold anywhere within over-erased distribution 106. By applying a programming pulse sufficient to correct a cell in a maximum over-erased state, a cell will be programmed out of the over-erased state no matter where within over-erased distribution 106 a threshold voltage of a cell presides. Because only a single pulse capable of correcting even the most over-erased bit is applied, a fast and power-efficient process is achieved.

When the programming pulse is applied, a threshold voltage of a cell may result in one of three states. First, a threshold voltage may fall within erase distribution 102 as seen for cell 108. Second, a threshold voltage may fall in-between erase distribution 102 and program distribution 104 as seen for cell 110. Third, it may fall within program distribution 104 as seen for cell 112. Although applying such a programming pulse may cause a single error by over-programming a once over-erased cell to a cell with a threshold voltage above an erase distribution, the overall error rate significantly drops. The “corrected” over-programmed cell is no longer lowering threshold voltages of electrically-coupled cells, which causes errors when those cells are read.

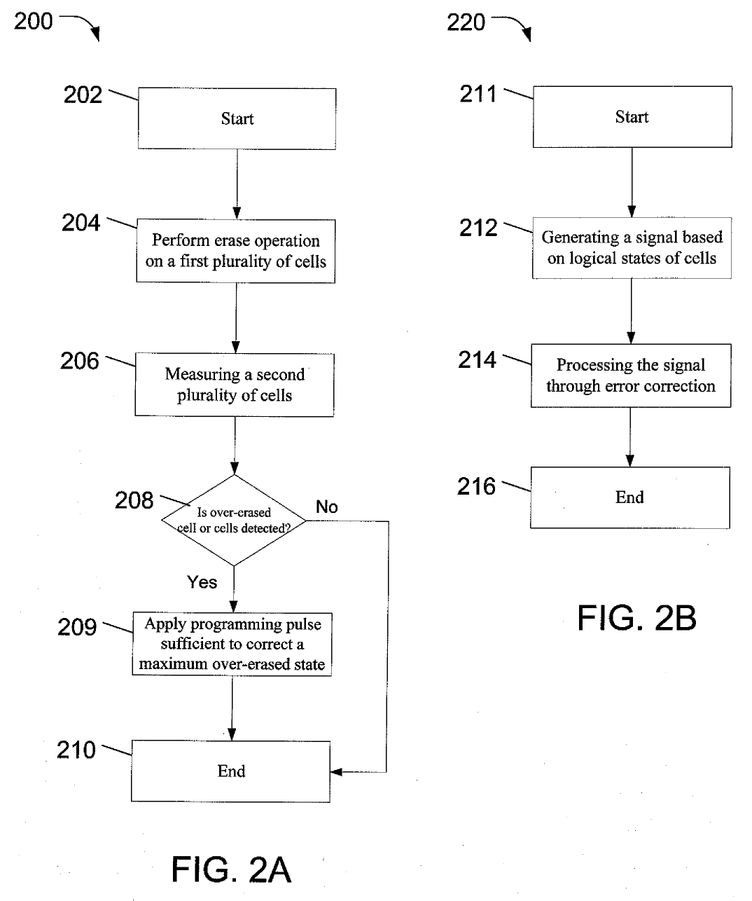

FIG. 2A is a flowchart of a process for correcting over-erased cells, in accordance with an embodiment of the invention. Process 200 starts at 202. At 204, process 200 performs an erase operation on a plurality of cells. The erase operation may be a block erase or any other type of erase technique for flash memory cells. At 206, a second plurality of cells is measured in order to detect an over-erased cell. The second plurality may be the same as, different from, or overlap with the first plurality. In one embodiment, measuring may comprise direct measurement of the erased cells or indirect measurement of neighboring cells to detect an over-erased cell. For example, if a first cell had a previously known state before an erase procedure, an erase procedure occurs on a second cell which is electrically coupled to the first cell, the first cell can be measured to determine if its state has changed. If so, it is likely that the second cell is over-erased.

At 208 a check is made to determine whether step 206 detected an over-erased cell or cells. If at least one over-erased cell is detected, then at 209 process 200 applies a programming pulse to the detected over-erased cell or cells sufficient to correct a cell in a maximum over-erased state as discussed above with reference to FIG. 1. The process ends at 210 after either no over-erased cell is found or the programming pulse is applied.

In some embodiments, the programming pulse may be a single programming pulse with electrical energy sufficient to correct a cell in a maximum over-erased state. It is within the scope of the present invention, however, to apply one or more programming pulses to an over-erased cell. In such embodiments, the one or more programming pulses may total a cumulative electrical energy sufficient to correct a cell in a maximum over-erased state. In some embodiments, the number of the one or more programming pulse is predetermined.

FIG. 2B is a flowchart of a process for reading memory cells, in accordance with an embodiment of the invention. Process 220 starts at 211. A signal is generated based on the logical states of the first and second plurality of cells (1 or 0, or in multi-bit embodiments 01, 10, etc . . . ) at 212. This may happen when a controller requests a data output from a flash memory.

At 214, the signal is processed through an error correction code. Embodiments of the present invention include both convolutional and block codes. Although process 200 may over-correct an over-erased cell so that it reads as a logical 1 instead of a 0 at 209, process 200 allows for a simple error correction code at 214 because the code only has to fix, in some cases, one bit. Some over-erased cells can cause erroneous readings of a whole column (or bitline) of a memory array, causing the number of errors to go beyond the capabilities of an error correction code. By applying a single programming pulse to over-erased cells at 209, an entire bitline of errors may be reduced to one or zero. After error correction at 214, process 220 ends at 216.

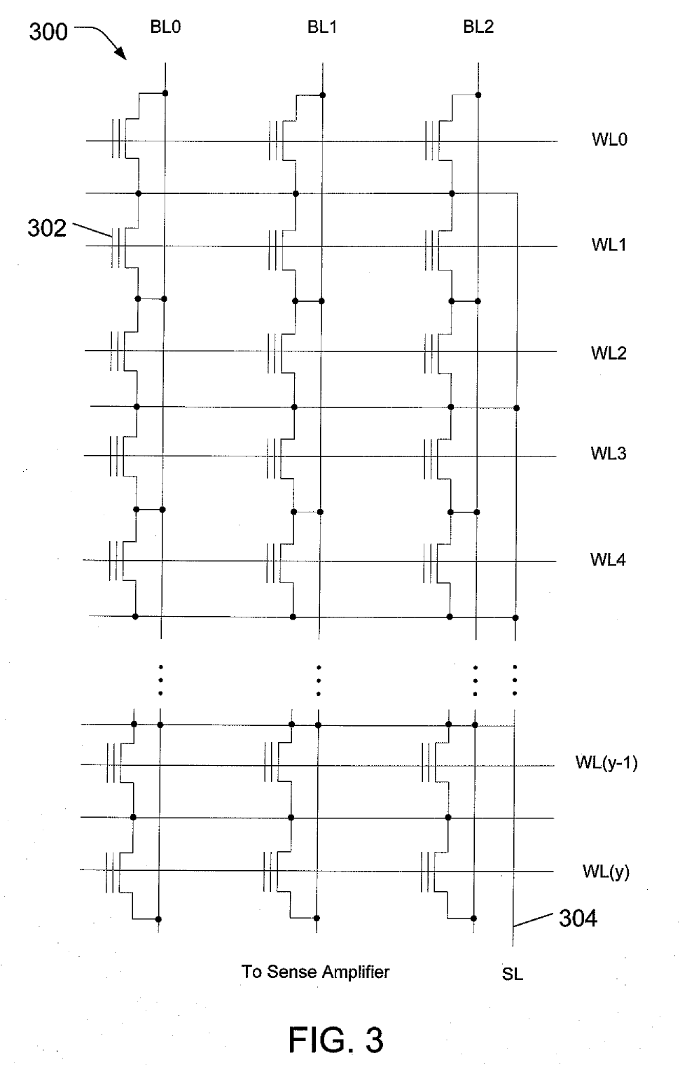

FIG. 3 shows simplified flash memory array 300 arranged similarly to a conventional NOR flash memory. Memory 300 consists of an array of cells 302 arranged in rows and columns. All cells 302 contain a floating gate to hold a charge, which enables control and alteration of the threshold voltage of a cell. Cells sharing the same gate form wordlines WL0-WLy. Cells sharing the same drain electrode form bitlines BL0-BL2. The source electrode 304 is common to all cells 302. Cells 302 are also connected to a sense amplifier. The sense amplifier compares voltages and/or currents of a cell to a reference in determining if a cell is erased, over-erased, under-erased, programmed, or over-programmed.

Flash memory array 300 is used for illustrative purposes only. The present invention is not limited to NOR or NOR-type flash memory. Alternative embodiments include other types of flash memory.

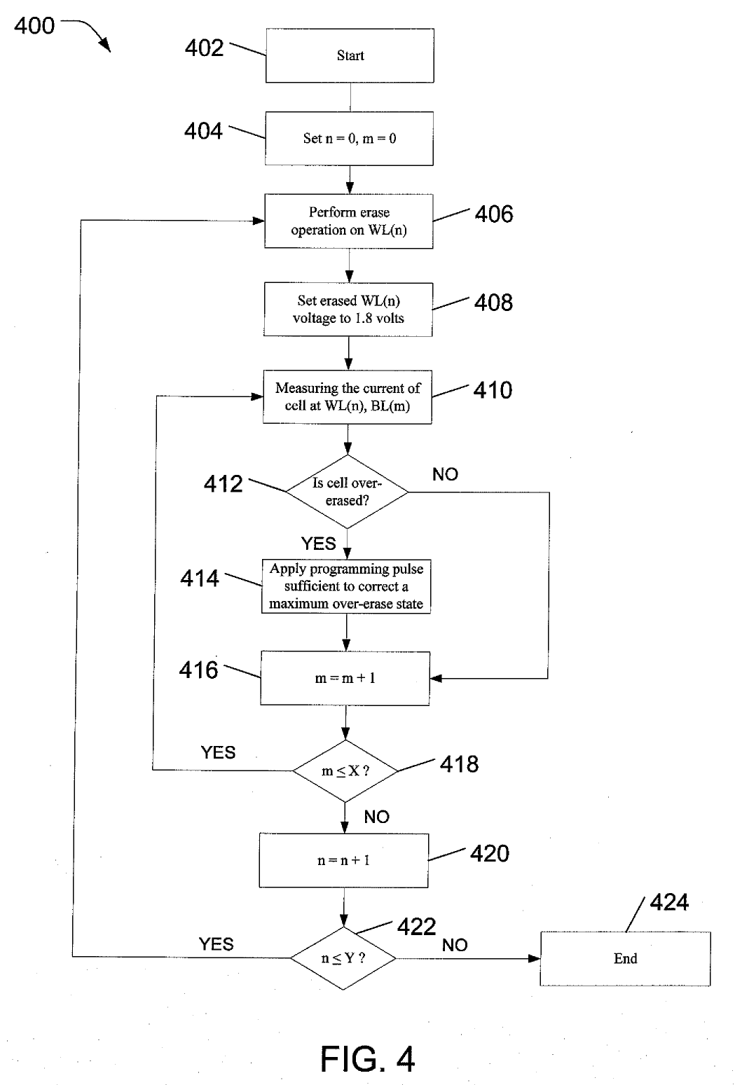

FIG. 4 shows a flow chart of a method of one embodiment of the invention, which may be applied to flash memory array 300 of FIG. 3. At 402, method 400 starts. At 404, n and m are set to zero. n represents which wordline method 400 is processing and m represents which cell method 400 is processing. Thus, method 400 would start with WL(0) of FIG. 3. It will be understood, however, that it is within the scope of the present invention to begin at any wordline.

At 406, the cells on WL(n) are erased. At 408, a voltage of, for example, 1.8 volts is applied to the erased wordline to measure the current of an erased cell. If a cell is over-erased, it will conduct more current than a cell with a threshold voltage within an erase distribution. At 410 the cell located at WL(n), BL(m) is measured. At 412, a check is made to determine if the measured cell is over-erased. In one embodiment, the current conducted by the cell is compared to a reference value. If the current is beyond a certain threshold of the reference value, the cell is over-erased. In an alternative embodiment, explained in more detail below, cells on surrounding wordlines may be measured, wherein the measurement of the cell current post-erase is compared to the cell current pre-erase. If a difference arises, then an over-erased cell exists on the same bit line.

If a cell is over-erased, then at 414 a programming pulse sufficient to correct a cell in a maximum over-erased state is applied to the cell. Either after the programming pulse is applied at 414 if the cell is over-erased or after the check at 412 if the cell is not over-erased, m is increased by one at 416 to check the next cell on the wordline. At 418, a check is made to determine if m is less than or equal to X. X is the number of cells on a wordline. If m is less than or equal to X then method 400 returns to 410 to measure the next cell on the wordline. If m is not less than or equal to X, then n is increased by one. A check is made at 422 to determine if n is less than or equal to Y. Y is the number of wordlines that are to be erased during an erase operation. This number may range from 1 to the total number of wordlines a memory array may contain. If n is less than or equal to Y, then method 400 returns to 406 to erase another wordline. If n is not less than or equal to Y, then the method ends at 424.

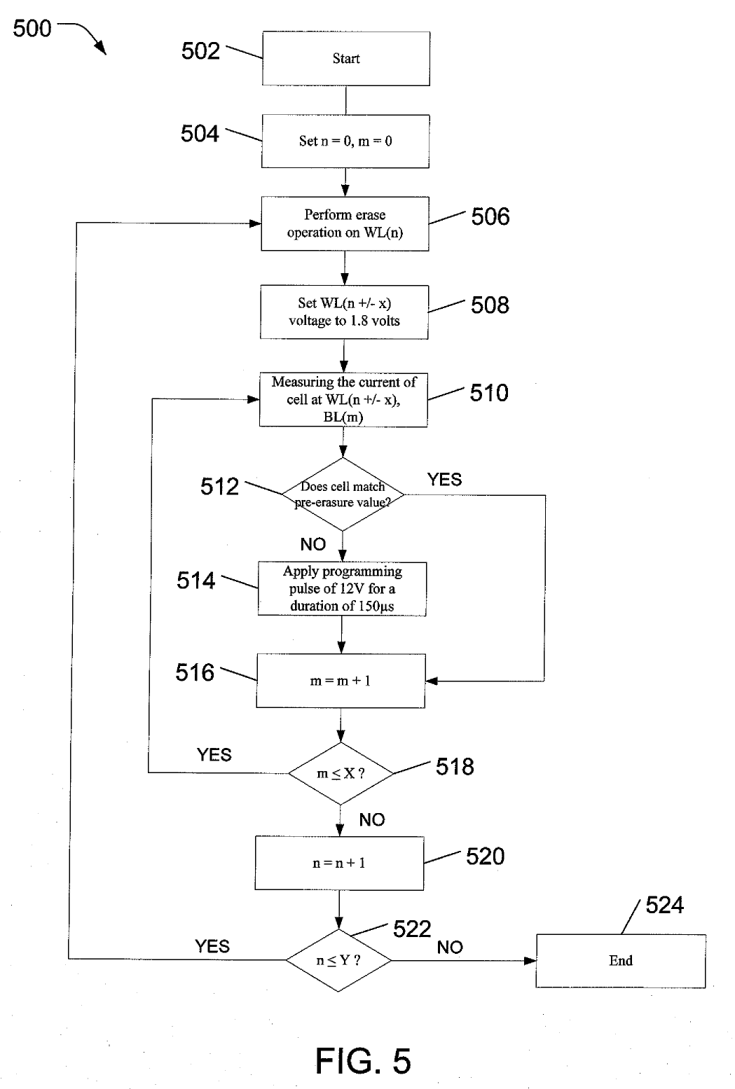

FIG. 5 shows a flow chart of a method of another embodiment of the invention, which may be applied to flash memory array 300 of FIG. 3. At 502, method 500 starts. At 504, n and m are set to zero. n represents which wordline method 500 is processing and m represents which cell method 500 is processing. Thus, method 500 would start with WL(0) of FIG. 3. It will be understood that it is within the scope of the present invention to begin at any wordline.

At 506, the cells on WL(n) are erased. At 508, voltage of, for example, 1.8 volts is applied to a wordline either above or below the now erased wordline. Since method 500 is checking for over-erased cells after each wordline erasure, if a cell above or below the erased wordline deviates from a previously known value, then a cell on the corresponding bitline of the erased wordline is over-erased. At 510, the cell located at WL(n±x), BL(m) is measured, with x being greater or equal to 1. At 512, a check is made to determine if the threshold voltage, state (erased or programmed), or some other value of the measured cell matches its previous know value before the wordline was erased. If a difference arises, then an over-erased cell exists on the same bit line of the erased wordline.

If a cell is over-erased, at 514 a programming pulse sufficient to correct a cell in a maximum over-erased state is applied to the cell. In this embodiment, such a pulse may be, for example, 12 volts for a duration of 150 μs. Either after the programming pulse is applied at 514 if the cell is over-erased or after the check at 512 if the cell is not over-erased, m is increased by one at 516 in order to check the next cell on the wordline. At 518, a check is made to determine if m is less than or equal to X. X is the number of cells on a wordline. If m is less than or equal to X then method 500 returns to 510 to measure the next cell on the wordline. If m is not less than or equal to X, then n is increased by one. A check is made at 522 to determine if n is less than or equal to Y. Y is the number of wordlines that are to be erased during an erase operation. This number may range from 1 to the total number of wordlines a memory array may contain. If n is less than or equal to Y, then method 500 returns to 506 to erase another wordline. If n is not less than or equal to Y, then the method ends at 524.

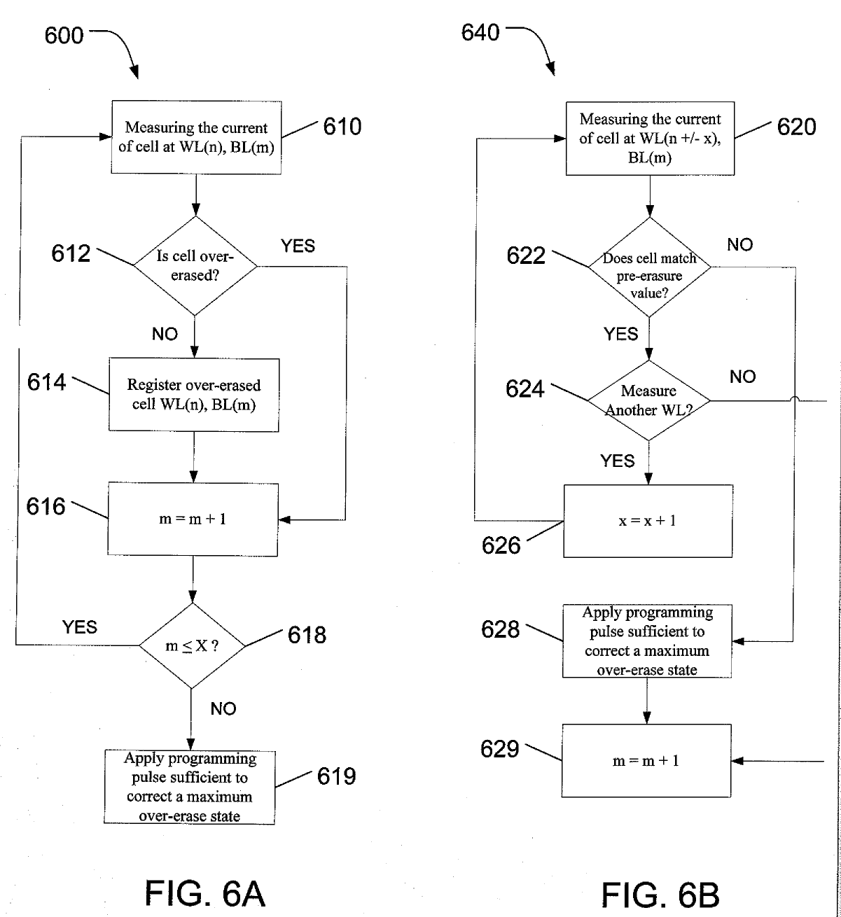

FIGS. 6A and 6B show flow charts of methods in accordance with embodiments of the invention, which may be applied to flash memory array 300 of FIG. 3. In FIG. 6A, method 600 begins at 610. At 610, the cell located at WL(n), BL(m) is measured. At 612, a check is made to determine if the measured cell is over-erased. If a cell is over-erased, then at 614 the over-erased cell is registered for programming in, for example, a controller. At 616, m is increased by one.

At 618, a check is made to determine if m is less than or equal to X. X is the number of cells on a wordline. If m is less than or equal to X then method 600 returns to 610 to measure the next cell on the wordline. If m is not less than or equal to X, then all of the cells on WL(n) have been measured. At 619, a programming pulse sufficient to correct a cell in a maximum over-erased state is applied to all the registered over-erased cells of the current wordline WL(n). Thus, the over-erased cells are programmed in parallel.

FIG. 6B shows another method in accordance with embodiments of the invention. In FIG. 6A, method 640 begins at 620. At 620, the cell located at WL(n±x), BL(m) is measured, with x being greater or equal to 1. At 622, a check is made to determine if the threshold voltage, state (erased or programmed), or some other value of the measured cell matches its previous know value before the wordline was erased.

If a difference is detected, then an over-erased cell exists on the same bit line of the erased wordline and method 640 applies to the over-erased cell a programming pulse sufficient to correct a cell in a maximum over-erased state at 628. If a difference is not detected, it is still possible that an over-erased cell resides on the current bitline because the over-erased cell may be only slightly over-erased and not affect the value of the measured cell. Since it is possible that an over-erased cell is affecting a pre-erasure value of another cell on the current bitline, at 624 a check is made to decide whether to measure another cell on the bitline or to move on to another bitline. At 626, x is increased by one and method 640 returns to 620 to measure another cell on BL(m). At 629, m is increased by one, wherein method 640 may measure another bitline.

The values given in FIGS. 1-6 are for illustration purposes only. As claimed in the present application, wordline read voltages and programming pulse voltage and duration are not limited to the above given values. Further, alternative embodiments to the above figures are also within the scope of the present application. For example, flash memory array of FIG. 3 may be composed of multi-bit cells.

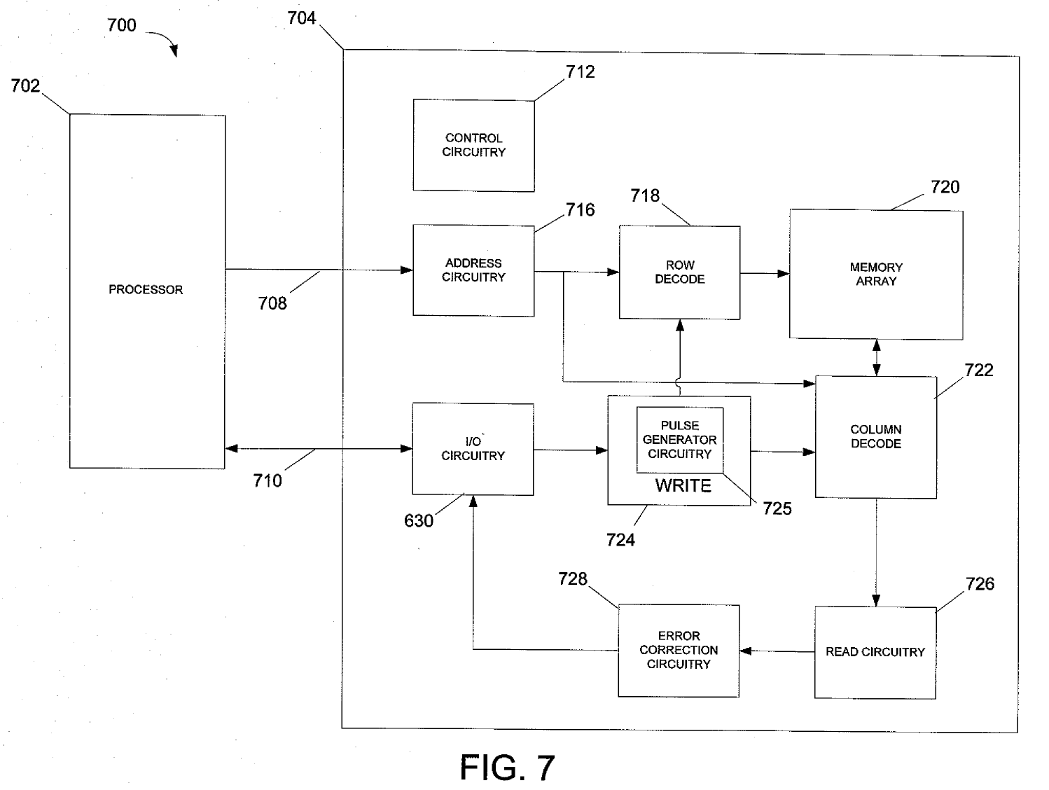

FIG. 7 illustrates a functional block diagram of memory device 704 of one embodiment of the present invention that may be coupled directly or indirectly (e.g., through a bus or memory controller) to processor 702. Coupling may be permanent or temporary. Processor 702 may be a microprocessor, a processor, or some other type of control circuitry. Memory device 704 and processor 702 form a part of electronic system 700.

Memory device 704 includes memory array 720. In one embodiment, memory cells (not shown) of memory array 720 are non-volatile floating-gate memory cells and arranged in arrays of columns and rows. Address circuitry 716 accepts address signals provided on address input connections 708. Address signals are received and decoded by row decoder 718 and column decoder 722 to access memory array 720.

Read circuitry 726 reads data stored in memory array 720. A data signal output from read circuitry 726 is accepted by error correction circuitry 728, which detects and corrects errors in the data signal. Embodiments include error correction circuitry which may be adapted to implement any number of error detection and correction schemes, including, but not limited to, checksums, cyclic redundancy check, Hamming code, Reed-Solomon code, BCH code, as well as other convolutional and block codes. Codes may be used individually or in tandem. In some embodiments, error correction circuitry 728 may be embedded in read circuitry 726. In some embodiments error detection and correction may be performed by CPU 702.

Data input and output circuitry 730 is included for bi-directional data communication over a plurality of data connections 710 with processor 702. Write circuitry 724 is provided to write data to memory array 720. In one embodiment, pulse generator circuitry 725 is located within write circuitry 724. Pulse generator circuitry 725 is adapted to provide a programming pulse sufficient to correct a cell in a maximum over-erased state.

In some embodiments, control circuitry 712 determines the maximum over-erased state of the memory device 704. In some embodiments the control circuitry 712 may update its definition of the maximum over-erased state to accommodate, for example, changing memory cell characteristics or erase operations.

In another embodiment, control circuitry 712 executes the erase methods of the present invention. For example, in some embodiments, control circuitry 712 registers one or more over-erased cells for programming and instructs pulse generator circuitry 725 to apply one or more programming pulses to the registered over-erased cells. Control circuitry 712 may be a state machine, a sequencer, or some other type of controller.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of correcting over-erased memory cells, the method comprising:
performing an erase operation on a first plurality of cells;
measuring at least one cell of a second plurality of cells; and
if one or more over-erased cells are detected in measuring the second plurality of cells, applying one or more programming pulses to the one or more over-erased cells, the one or more programming pulses cumulatively sufficient to correct a cell in a maximum over-erased state.

2. The method of claim 1, wherein applying the one or more programming pulses to the one or more over-erased cells comprises applying the one or more programming pulses totaling a cumulative electrical energy sufficient to correct the cell in the maximum over-erased state.

3. The method of claim 1, wherein applying the one or more programming pulses to the one or more over-erased cells comprises applying a single programming pulse to the one or more over-erased cells.

4. The method of claim 1, wherein applying the one or more programming pulses to the one or more over-erased cells comprises applying a predetermined number of pulses to the one or more over-erased cells.

5. The method of claim 3, wherein applying the single programming pulse to the one or more over-erased cells comprises applying the singe programming pulse to the one or more over-erased cells, wherein the single programming pulse is of a predetermined amplitude.

6. The method of claim 3, wherein applying the single programming pulse to the one or more over-erased cells comprises applying the single programming pulse to the one or more over-erased cells, wherein the single programming pulse is of a predetermined length.

7. The method of claim 3, wherein applying the single programming pulse to the one or more over-erased cells comprises applying the single programming pulse to the one or more over-erased cells, wherein the single programming pulse is of a predetermined amplitude and a predetermined length.

8. The method of claim 3, wherein applying the single programming pulse to the one or more over-erased cells comprises applying the single programming pulse of 12 volts for a duration of 150 μs to the one or more over-erased cells.

9. The method of claim 1, wherein measuring at least one of the second plurality of cells comprises measuring at least one of the second plurality of cells, wherein the first plurality of cells and the second plurality of cells share at least one cell in common.

10. The method of claim 1, wherein performing the erase operation on the first plurality of cells comprises performing the erase operation on at least one wordline of NOR memory.

11. The method claim 1, further comprising:
continuing measuring the second plurality of cells and applying the one or more programming pulses to the one or more over-erased cells until the first plurality of cells is free of over-erase errors.

12. The method claim 1, further comprising:
generating a signal based on a logical state of at least one cell of the first or second plurality of cells; and
error correcting at least a portion of the signal.

13. A method of correcting a series of errors in a flash memory, the method comprising:
detecting an over-erased cell, wherein the over-erased cell prevents at least one other cell from being properly read; and
applying one or more programming pulses to the over-erased cell, the one or more programming cumulatively sufficient to correct a cell in a maximum over-erased state.

14. A method of correcting over-erased memory cells, the method comprising:
performing an erase operation on a first plurality of cells;
measuring at least one cell of a second plurality of cells;
if one or more over-erased cells are detected in measuring the second plurality of cells, registering the one or more over-erased cells for programming; and
applying one or more programming pulses to the registered over-erased cells, the one or more programming pulses cumulatively sufficient to correct a cell in a maximum over-erased state.

15. A flash memory device, the device comprising:
a plurality of flash memory cells;
erase circuitry;
measuring circuitry, the measuring circuitry adapted to detect an over-erased cell in the plurality of cells; and
a pulse generator, the pulse generator adapted to apply to the over-erased cell one or more programming pulses cumulatively sufficient to correct a cell in a maximum over-erased state.

16. The flash memory device of claim 15, wherein the pulse generator is further adapted to apply a predetermined number of pulses to the over-erased cell.

17. The flash memory device of claim 15, wherein the pulse generator is further adapted to apply a single programming pulse to the over-erased cell.

18. The flash memory device of claim 15, wherein the pulse generator is further adapted to apply the single programming pulse to the over-erased cell, the programming pulse being of a predetermined amplitude.

19. The flash memory device of claim 15, wherein the pulse generator is further adapted to apply the single programming pulse to the over-erased cell, the programming pulse being of a predetermined length.

20. The flash memory device of claim 15, wherein the pulse generator is further adapted to apply the single programming pulse to the over-erased cell, the programming pulse being of a predetermined amplitude and a predetermined length.

21. The flash memory device of claim 15, wherein the plurality of flash memory cells comprise NOR memory cells.

22. The flash memory device of claim 15 wherein the plurality of flash memory cells comprise multi-bit flash memory cells.

23. The flash memory device of claim 15, further comprising error correction circuitry.

24. The flash memory device of claim 15, further comprising a controller, the controller adapted to determine the maximum over-erased state of the flash memory device.

25. The flash memory device of claim 15, further comprising a controller, the controller adapted to:
register the over-erased cell for programming; and
control the pulse generator to apply the one or more programming pulses to the registered over-erased cells.
